(19) United States
(12) Patent Application Publication
(10) Pub. No.: US 2026/0156840 A1
(43) Pub. Date: Jun. 4, 2026

(54) MEMORY

(71) Applicant: CXMT Corporation, Hefei City (CN)

(72) Inventors: Binxi LIANG, Hefei City (CN); Zufa ZHANG, Hefei City (CN)

(73) Assignee: CXMT Corporation, Hefei City (CN)

(21) Appl. No.: 19/432,945

(22) Filed: Dec. 25, 2025

Related U.S. Application Data
(63) Continuation of application No. PCT/CN2025/132848, filed on Nov. 5, 2025.

(30) Foreign Application Priority Data
Dec. 2, 2024 (CN) 202411784548.X

(51) Int. Cl. H10B 80/00; H10W 90/00; H10W 90/20

(52) U.S. Cl. CPC H10B 80/00; H10W 90/297; H10W 90/792

(57) ABSTRACT

Embodiments of the present application relate to the field of memories and provide a memory. The memory includes a first chip, a second chip, a third chip, and a fourth chip stacked in sequence along a first direction, where a logic circuit is formed on the first chip, a first memory array is formed on the second chip, a core region circuit is formed on the third chip, and a second memory array is formed on the fourth chip.

This is a continuation of International Patent Application No. PCT/CN2025/132848 filed on Nov. 5, 2025, which claims priority to Chinese Patent Application No. 202411784548.X, filed on Dec. 2, 2024. The disclosures of the above-referenced applications are hereby incorporated by reference in their entirety.

### BACKGROUND

A conventional memory chip is manufactured based on a two-dimensional plane, and memory cells are arranged on one plane. However, as the demand for memories with higher capacity and smaller size continues to increase, the conventional two-dimensional planar memory technology is faced with physical and performance limitations.

In order to solve these problems, the three-dimensional memory technology has emerged. It achieves higher storage density by stacking multiple layers of memory cells in the vertical direction. Such a stack structure can significantly increase the storage capacity of the memory chip while keeping the chip size relatively small. In addition, the three-dimensional memory also adopts advanced manufacturing processes and materials to improve data transmission speed and efficiency.

In existing three-dimensional memories, all memory cells are disposed on one chip, and all circuit structures are disposed on another chip. However, this design may cause a waste of area due to the requirement of the memory cell for driving capability and the requirement of circuit layout.

### SUMMARY

The present disclosure relates to the field of semiconductor technologies, and in particular, to a memory, which is at least beneficial to solving the problem of the waste of the area of a memory array chip in a three-dimensional memory.

According to some embodiments of the present application, an aspect of the embodiments of the present application provides a memory. The memory includes a first chip, a second chip, a third chip, and a fourth chip stacked in sequence along a first direction, where a logic circuit is formed on the first chip, a first memory array is formed on the second chip, a core region circuit is formed on the third chip, and a second memory array is formed on the fourth chip.

In some embodiments, the core region circuit includes a sense amplifier.

In some embodiments, the sense amplifier is connected to the first memory array through a first bitline, and the sense amplifier is connected to the second memory array through a first complementary bitline.

In some embodiments, the sense amplifier has different driving capabilities for the first bitline and the first complementary bitline.

In some embodiments, the sense amplifier includes a first inverter and a second inverter connected end to end, and the first inverter and the second inverter have different driving capabilities.

In some embodiments, the core region circuit includes a sub-wordline driver array, the sub-wordline driver array includes a first sub-wordline driver and a second sub-wordline driver, the first sub-wordline driver is connected to the first memory array through a first sub-wordline, and the second sub-wordline driver is connected to the second memory array through a second sub-wordline.

In some embodiments, the first sub-wordline driver and the second sub-wordline driver have different driving capabilities.

In some embodiments, the core region circuit further includes a row decoder, a column decoder, and a low dropout linear regulator.

In some embodiments, the core region circuit is disposed on a side, facing the fourth chip, of the third chip, and the electrical connection path between the core region circuit and the first chip includes: a through-silicon via penetrating through the third chip, hybrid bonding between the third chip and the second chip, a through-silicon via penetrating through the second chip, and hybrid bonding between the second chip and the first chip.

In some embodiments, the core region circuit is disposed on a side, facing the second chip, of the third chip, and the electrical connection path between the core region circuit and the first chip includes: hybrid bonding between the third chip and the second chip, a through-silicon via penetrating through the second chip, and hybrid bonding between the second chip and the first chip.

The technical solutions provided according to the embodiments of the present application at least have the following advantages:

The memory includes a first chip, a second chip, a third chip, and a fourth chip stacked in sequence along a first direction, where a logic circuit is formed on the first chip, a first memory array is formed on the second chip, a core region circuit is formed on the third chip, and a second memory array is formed on the fourth chip, thus forming a four-layer “memory array-core region circuit-memory array-logic circuit” chip stack mode. Compared with a conventional two-layer “memory array-circuit” chip stack structure, in the present application, the core region circuit closely associated with reading and writing data information of the memory arrays is separately placed in an independent chip to drive or read data information stored in the memory arrays on two sides of the chip, and the logic circuit of the peripheral region is placed in a separate chip located on the other side. In this way, the memory array chip does not need to provide an inactive area corresponding to the peripheral region circuit, such that an almost 100% utilization of the memory array chip can be achieved, thereby achieving a higher die per wafer (die per wafer, DPW).

In addition, because the sense amplifier can sense and amplify memory cells on chips on two sides, the problem of an edge memory array (edge MAT) can be resolved, and the utilization of the memory array and the sense amplifier can be improved.

### BRIEF DESCRIPTION OF DRAWINGS

One or more embodiments are illustrated by images in corresponding drawings, and these exemplary explanations are not to be construed as limiting the embodiments. Unless expressly stated otherwise, the images in the drawings do not constitute a proportion limitation.

FIG. 1 is a schematic diagram of the layout of a two-layer chip stack structure;

FIG. 2 is a schematic structural diagram of a memory provided according to an embodiment of the present disclosure;

FIG. 3 is a schematic diagram of one detailed layout of a memory provided according to an embodiment of the present disclosure;

FIG. 4 is a schematic diagram of a connection relationship between a sense amplifier array and a memory array provided according to an embodiment of the present disclosure;

FIG. 5 is a schematic structural diagram of an asymmetric sense amplifier provided according to an embodiment of the present disclosure; and

FIG. 6 is a schematic diagram of another detailed layout of a memory provided according to an embodiment of the present disclosure.

### DESCRIPTION OF EMBODIMENTS

Exemplary embodiments of the present disclosure will be described in detail below with reference to the drawings, such that those skilled in the art can easily practice the present disclosure. As those skilled in the art will recognize, the described embodiments may be modified in various ways, all without departing from the spirit or scope of the present disclosure. For example, the exemplary embodiments provided herein are considered to be capable of being combined in whole or in part for implementation. Specifically, an element described in a particular exemplary embodiment, even if not described in another exemplary embodiment, can be understood as a description relating to another exemplary embodiment, unless a contrary or contradictory description is provided therein.

Throughout this specification, when any part is referred to as being “connected” to another part, it includes the case where any part and another part are “indirectly connected” to each other with other parts interposed therebetween and the case where any part and another part are “directly connected” to each other. For example, it should be understood that when an element is referred to as being “connected” or “coupled” to another element, or “on” another element, it can be directly connected or coupled to another element or directly on another element, or an intervening element may be present. In contrast, when an element is referred to as being “directly connected” or “directly coupled” to another element, or “in contact with” another element, no intervening elements are present at the point of contact.

Furthermore, “electrically connected” conceptually includes being physically connected and being physically disconnected. It can be understood that when terms such as “first” and “second” are used to refer to an element, the element is not so limited. They may be used only for the purpose of distinguishing one element from another and may not limit the order or importance of the elements. In some cases, the first element may be termed the second element without departing from the scope of the claims set forth herein. Similarly, the second element may also be termed the first element.

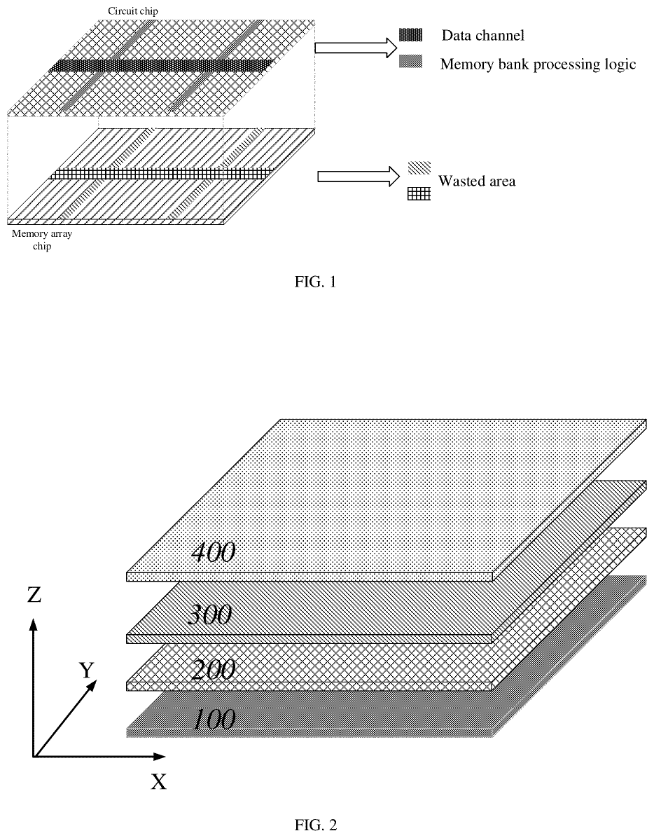

FIG. 1 is a schematic diagram of the layout of a two-layer “memory array-circuit” chip stack structure in the prior art. In the structure of a three-dimensional memory, a chip on which a memory array composed of memory cells is formed and a chip on which a circuit for performing a data read/write operation on the memory array is formed are bonded together through, for example, hybrid bonding by using the wafer-on-wafer (wafer-on-wafer, WoW) bonding technology, thus achieving high-density storage. Charge information stored in the memory cells in the memory array chip can be written and read only after the operations by circuits such as a sense amplifier (sense amplifier, SA) and a sub-wordline driving circuit (sub-wordline driver, SWD). In order to ensure that the memory information can be read correctly and quickly, a sense amplifier and a sub-wordline driving circuit are placed right above each memory array tile (memory array tile, MAT) in the memory array, i.e., at a position on the circuit chip corresponding to the memory array tile. Since the area of the sense amplifier and the sub-wordline driving circuit is smaller than the area of the corresponding memory array tile, many fragmented blank regions (as shown in FIG. 1) will be left after the sense amplifier and the sub-wordline driver are arranged on the circuit chip. Because it is difficult to accommodate a relatively complete circuit in these fragmented regions, this part of area is wasted. Due to the feature that the core region circuits on the circuit chip and the memory array tiles of the memory array chip are arranged in one-to-one correspondence, the circuit chip of the three-dimensional memory also needs an additional area for accommodating modules such as a row decoder (row decoder, XDEC), a column decoder (column decoder, YDEC), a memory bank processing logic (Bank Logic) circuit, and a data channel (Channel) circuit. Therefore, in such a two-layer “memory array-circuit” chip stack structure, the occupied area of the circuit chip cannot be entirely placed above the memory array tile, and the memory array chip needs to reserve an extra area to correspond to the area of the row decoder, the column decoder, the memory bank processing logic circuit, and the data channel circuit modules. This results in a waste of the area of the memory array chip and a reduction in wafer utilization.

Based on this, the present application provides a memory. The memory includes a first chip, a second chip, a third chip, and a fourth chip stacked in sequence along a first direction, where a logic circuit is formed on the first chip, a first memory array is formed on the second chip, a core region circuit is formed on the third chip, and a second memory array is formed on the fourth chip, thus forming a four-layer “memory array-core region circuit-memory array-logic circuit” chip stack mode. Compared with a conventional two-layer “memory array-circuit” chip stack structure, in the present application, the core region circuit closely associated with reading and writing data information of the memory arrays is separately placed in an independent chip to drive or read data information stored in the memory arrays on two sides of the chip, and the logic circuit of the peripheral region is placed in a separate chip located on the other side. In this way, the memory array chip does not need to provide an inactive area corresponding to the peripheral region circuit, such that an almost 100% utilization of the memory array chip can be achieved, thereby achieving a higher die per wafer (die per wafer, DPW).

In addition, because the sense amplifier can sense and amplify memory cells on chips on two sides, the problem of an edge memory array (edge MAT) can be resolved, and the utilization of the memory array and the sense amplifier can be improved.

The embodiments of the present application will be described in detail below with reference to the drawings. Those of ordinary skill in the art can understand that, in the embodiments of the present application, numerous technical details are set forth in order to enable readers to better understand the present application. However, the technical solutions claimed by the present application can also be implemented even without these technical details and the various changes and modifications based on the following embodiments.

FIG. 2 is a schematic structural diagram of a memory provided according to an embodiment of the present disclosure. Referring to FIG. 2, a memory includes a first chip 100, a second chip 200, a third chip 300, and a fourth chip 400 stacked in sequence along a first direction Z, where a logic circuit is formed on the first chip 100, a first memory array is formed on the second chip, a core region circuit is formed on the third chip, and a second memory array is formed on the fourth chip.

Therefore, a four-layer “memory array-core region circuit-memory array-logic circuit” chip stack structure is formed. Compared with a conventional two-layer “memory array-circuit” chip stack structure, in this embodiment, the core region circuit closely associated with reading and writing data information of the memory arrays is separately placed in an independent chip to drive or read data information stored in the memory arrays on two sides of the chip, and the logic circuit of the peripheral region is placed in a separate chip located on the other side. In this way, the memory array chip does not need to provide an inactive area corresponding to the peripheral region circuit, such that an almost 100% utilization of the memory array chip can be achieved, thereby improving the wafer utilization.

In FIG. 2, each of the first chip to the fourth chip extends along a second direction X and a third direction Y. The first direction Z, the second direction X, and the third direction Y are perpendicular to each other.

In the following examples, a dynamic random access memory (DRAM) is used as an example. However, it should be understood that the present application is also applicable to other types of memories, such as a static random access memory (SRAM), a magnetic random access memory (MRAM), a phase change memory (PRAM), a ferroelectric random access memory (FeRAM), and a flash memory (such as a NAND flash and a Nor flash).

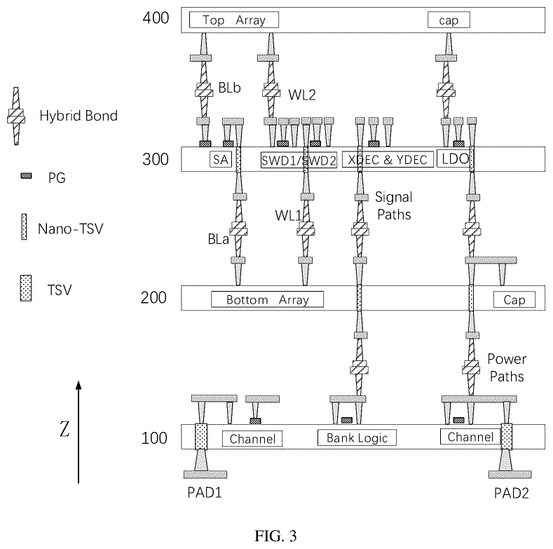

In some embodiments, circuit details in each chip of FIG. 2 may be shown in FIG. 3. Referring to FIG. 3, the logic circuit formed on the first chip 100 includes a data channel circuit Channel and a memory bank logic circuit Bank Logic. The data channel circuit Channel includes circuits such as a data receiving circuit, a parallel-to-serial conversion circuit, a data driving circuit, a data transmitting circuit, and a control circuit. The memory bank logic circuit Bank Logic includes a logic circuit that controls each bank (bank), such as a refresh-related control circuit and an error checking and correcting circuit (ECC). An input/output pad PAD1 for signals such as a data signal DQ, a command address signal CA, and a data strobe signal DQS is also formed on the surface of the first chip 100. It should be noted that the PAD1 herein only represents one type of pad, and does not represent that there is only one pad. There may be a plurality of PAD1s. An input/output pad PAD2 for a power supply signal is also formed on the surface of the first chip 100. It should be understood that there may also be a plurality of PAD2s herein, depending on the quantity actually required. For example, the PAD2 may include a pad connected to the power supply of various high-level signals, or may include a pad connected to the power supply of a low-level signal.

In the embodiment of FIG. 3, the logic circuit is formed on a surface of a side, proximal to the second chip 200, of the first chip 100, and a surface electrical connection circuit is also formed on the surface of the side, proximal to the second chip 200, of the first chip 100 to achieve the electrical connection between the surface of the first chip 100 and other chips in the stack structure. A through-silicon via TSV is also formed in the first chip 100, the pads PAD1 and PAD2 are formed on a surface of a side, distal to the second chip 200, of the first chip 100, and the through-silicon via TSV is configured to electrically connect the logic circuit on the surface of the first chip 100 to the pads PAD1 and PAD2 on the other surface, such that the logic circuit of the first chip 100 and a circuit electrically connected to the logic circuit of the first chip 100 are electrically led out through the pads PAD1 and PAD2.

The second chip 200 and the fourth chip 400 may be completely the same, such that they may be manufactured by using the same process, thereby reducing process complexity and saving the process. In some other embodiments, the second chip 200 and the fourth chip 400 may also be of different structures to be compatible with different storage capacities, thereby increasing the flexibility.

Referring to FIG. 3, memory arrays are formed on the second chip 200 and the fourth chip 400. In FIG. 3, a Bottom Array represents the first memory array in the second chip 200, and a Top Array represents the second memory array in the fourth chip 400. The memory array is formed by arranging memory cells in an array. The memory array tile MAT and the memory bank Bank are both memory arrays. For a DRAM, the memory cell may be composed of one transistor and one capacitor (1T1C). In some other embodiments, the memory cell may also be composed of two transistors and zero capacitors (2T0C) or one transistor and zero capacitors (1T0C). This is not specifically limited in the present application.

Referring to FIG. 3, a capacitor Cap may also be formed in the memory array to serve as a power terminal for receiving and outputting power.

With continued reference to FIG. 3, a core region circuit is formed on the third chip 300, and the core region circuit may include a sense amplifier SA, a sub-wordline driver SWD, a row decoder XDEC, and a column decoder YDEC. Specifically, the core region circuit may include a sense amplifier array. The sense amplifier array includes a plurality of sense amplifiers, and the sense amplifier arrays are in one-to-one correspondence with the memory arrays. In consideration of the area ratio of the memory array to the sense amplifier, the sense amplifier is disposed on the third chip to amplify the memory arrays on the two sides, such that the area of the memory arrays on the second chip and the fourth chip can be fully utilized.

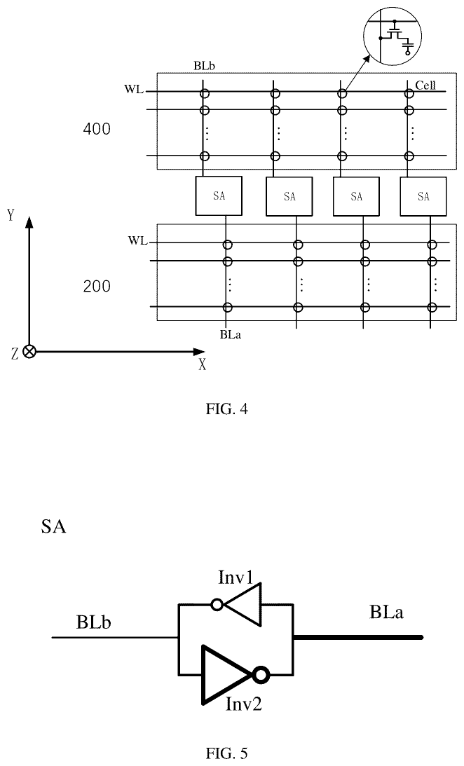

FIG. 4 is a schematic diagram of a connection relationship between a sense amplifier array and a memory array provided according to an embodiment of the present disclosure. The third chip 300 is provided with sense amplifiers SA, and the sense amplifiers SA are arranged in an array. The sense amplifiers SA are connected to the first memory array Bottom Array on the second chip 200 through first bitlines BLa, and the sense amplifiers SA are connected to the second memory array Top Array on the fourth chip 400 through first complementary bitlines BLb.

In FIG. 4, the memory cells are arranged in an array of rows and columns, the memory cells in each row are driven by the same wordline WL, and the memory cells in the same column are read by the same bitline BL. Each memory cell Cell includes, for example, one transistor and one capacitor structure.

The first bitline BLa and the first complementary bitline BLb are two bitlines whose charge difference is sensed and amplified by the same sense amplifier SA. That is, the memory cells on the first memory array are connected to a sense amplifier SA through the first bitline BLa, and the memory cells on the second memory array are connected to this sense amplifier SA through the first complementary bitline BLb. When the data stored in the memory cells on the first memory array is read, the charge amount on the first bitline BLa changes, and the sense amplifier uses the voltage level on the first complementary bitline BLb as a reference value to detect the weak signal change on the first bitline BLa and amplify it to a level that can be read, thereby reading out the data stored in the memory cells on the first memory array. On the contrary, when the data stored in the memory cells on the second memory array is read, the charge amount on the first complementary bitline BLb changes, and the sense amplifier uses the voltage level on the first bitline BLa as a reference value to detect the weak signal change on the first complementary bitline BLb and amplify it to a level that can be read, thereby reading the data stored in the memory cells on the second memory array.

Therefore, since the sense amplifier can sense and amplify the memory cells on the second chip and the fourth chip, and the second chip and the fourth chip are located on two sides of the sense amplifier and are thus naturally paired, the problem that there is no corresponding complementary bitline for the bitline of the memory array at the edge (edge MAT) can be resolved, thereby improving the utilization of the memory array and the sense amplifier. In addition, because the sense amplifier array is located between the second chip and the fourth chip, the same hybrid bonding manner may be applied between the second chip and the third chip and between the third chip and the fourth chip. This increases the matching degree between the path from the sense amplifier to the second chip and the path from the sense amplifier to the fourth chip, and reduces asymmetry.

In some other embodiments, the sense amplifier SA may also sense and amplify a charge difference only for two bitlines on the second chip 200 or two bitlines on the fourth chip 400. That is, the sense amplifier SA is connected to a memory cell on the second chip 200 through a first bitline and is also connected to another memory cell on the second chip 200 through a first complementary bitline. Alternatively, the sense amplifier SA is connected to a memory cell on the fourth chip 400 through a first bitline and is also connected to another memory cell on the fourth chip 400 through a first complementary bitline. When the storage capacities of the second chip 200 and the fourth chip 400 are not equal, some sense amplifiers SA may be connected to only the chip on one side to sense and amplify only data on the chip on this side. For example, if the storage capacity of the fourth chip 400 is greater than that of the second chip 200, for the portion with the same storage capacity, the first bitline and the first complementary bitline connected to the sense amplifier SA are from the second chip 200 and the fourth chip 400, respectively; for the portion of the fourth chip 400 with a higher storage capacity than the second chip 200, the first bitline and the first complementary bitline connected to the sense amplifier SA are both from the fourth chip 400.

In some embodiments, in order to further improve the symmetry, the sense amplifier SA has different driving capabilities for the first bitline BLa and the first complementary bitline BLb.

In the example of FIG. 3, the sense amplifier SA is formed on a side, facing the fourth chip 400, of the third chip 300. For ease of description, an upper surface and a lower surface are used for description below. In FIG. 3, a side, facing the fourth chip 400, of the third chip 300 is the upper surface of the third chip 300, and a side, facing the second chip 200, of the third chip 300 is the lower surface of the third chip 300. Because the third chip 300 has a certain thickness, a circuit on the upper surface requires a through-silicon via TSV to be electrically connected to the lower surface of the chip, thus being electrically connected to the second chip 200 at the lower surface. That is, when the sense amplifier SA is formed on the upper surface of the chip, the sense amplifier SA may be directly connected to the second memory array Top Array at the upper surface through hybrid bonding, but the sense amplifier needs to be first routed to the lower surface through the through-silicon via TSV and then connected to the first memory array Bottom Array at the lower surface through hybrid bonding on the lower surface. In some embodiments, the sense amplifier SA also needs to be first connected to the through-silicon via TSV through the interconnection metal line layer of the upper surface before being connected to the lower surface through the through-silicon via TSV. Since the first bitline BLa needs to pass through at least one additional through-silicon via TSV layer, a bitline load mismatch exists between the bitline and the complementary bitline. Therefore, by providing the asymmetric sense amplifier, the sense amplifier has different driving capabilities for the first bitline BLa and the first complementary bitline BLb, such that the load mismatch between the bitline and the complementary bitline can be compensated as needed.

FIG. 5 is a schematic structural diagram of an asymmetric sense amplifier provided according to an embodiment of the present disclosure. As shown in FIG. 5, the sense amplifier includes a first inverter Inv1 and a second inverter Inv2 connected end to end, and the first inverter Inv1 and the second inverter Inv2 have different driving capabilities. For example, the driving capability of the first inverter Inv1 may be weaker than the driving capability of the second inverter Inv2, the first inverter Inv1 with a weaker driving capability may be configured to drive the bitline with a smaller load, and the second inverter Inv2 with a stronger driving capability may be configured to drive the bitline with a larger load.

In the embodiment of FIG. 3, the sense amplifier SA is located on the upper surface of the third chip 300, and the sense amplifier SA also requires a through-silicon via TSV to connect to the first memory array Bottom Array. Thus, the load of the first bitline BLa is greater than the load of the first complementary bitline BLb. Correspondingly, the driving capability of the first inverter Inv1 is weaker than the driving capability of the second inverter Inv2, the first inverter Inv1 with a weaker driving capability is configured to drive the first complementary bitline BLb with a smaller load, and the second inverter Inv2 with a stronger driving capability may be configured to drive the first bitline BLa with a larger load.

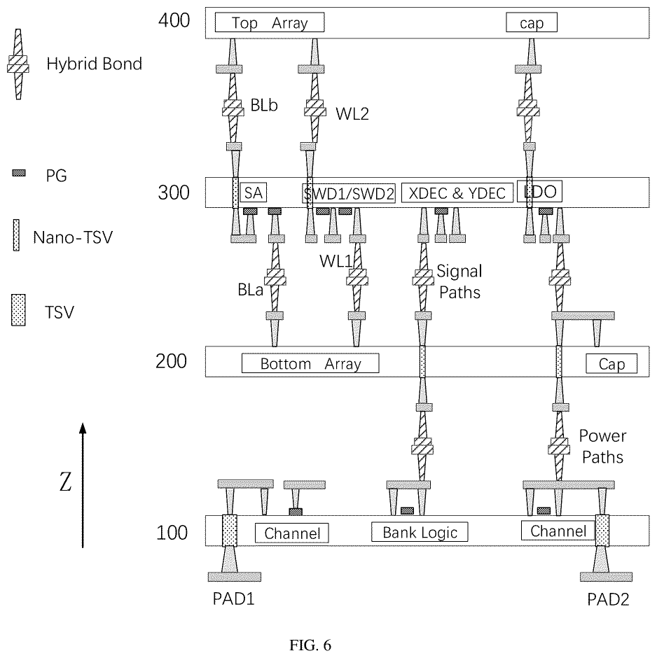

FIG. 6 is a schematic diagram showing another detailed layout of a memory provided according to an embodiment of the present disclosure. In FIG. 6, the sense amplifier SA is formed on the lower surface of the third chip 300. The sense amplifier SA also requires a through-silicon via TSV to connect to the second memory array Top Array, and thus the load of the first complementary bitline BLb is greater than the load of the first bitline BLa. Correspondingly, the driving capability of the first inverter Inv1 may be set to be stronger than the driving capability of the second inverter Inv2. The first inverter Inv1 with a stronger driving capability is configured to drive the first complementary bitline BLb with a larger load, and the second inverter Inv2 with a weaker driving capability may be configured to drive the first bitline BLa with a smaller load.

Therefore, through the asymmetric inverter design, different degrees of driving may be applied to the bitlines with different loads, thereby compensating for the load mismatch, improving the circuit symmetry, and facilitating the correct sensing and amplification of the sense amplifier.

There are two types of through-silicon vias, i.e., a through-silicon via of a conventional size (TSV) and a through-silicon via of a micro size (Nano-TSV). The size of the through-silicon via of a conventional size is greater than that of the through-silicon via of a micro size. In some embodiments, since the through-silicon vias TSV may cause a load mismatch of the bitlines, as shown in FIG. 3, the through-silicon vias TSV on the third chip 300 may be micro TSVs to reduce the load introduced by the TSVs and further reduce the load mismatch of the bitlines.

In some embodiments, the driving capability of the asymmetric inverter can be designed by using asymmetric transistors. An inverter with a stronger driving capability may be implemented by using a relatively large W/L (width/length) ratio. In some other embodiments, the asymmetric inverter may also be implemented by using an asymmetric power supply voltage. The inverter with a stronger driving capability receives a larger power supply voltage VDD.

In some other embodiments, loads on different bitlines may also be matched by asymmetric trace lengths. For example, for a bitline that does not contain the load of a through-silicon via TSV, longer routing may be implemented to increase its load, thus matching the load introduced by the through-silicon via TSV.

In some embodiments, the core region circuit on the third chip 300 further includes a sub-wordline driver array formed by arranging a plurality of sub-wordline drivers SWD. Referring to FIG. 3, the sub-wordline driver array includes a first sub-wordline driver SWD1 and a second sub-wordline driver SWD2. The first sub-wordline driver SWD1 is connected to the first memory array Bottom Array through a first sub-wordline WL1, and the second sub-wordline driver SWD2 is connected to the second memory array Top Array through a second sub-wordline WL2.

That is, the first memory array and the second memory array are driven by different sub-wordline drivers, such that the corresponding sub-wordline drivers can be specifically adjusted and designed based on the positions of the first memory array and the second memory array, thereby flexibly controlling the reading and writing of the first memory array and the second memory array.

In some embodiments, the first sub-wordline driver SWD1 and the second sub-wordline driver SWD2 have different driving capabilities.

Specifically, in the embodiment of FIG. 3, like the sense amplifier SA, the sub-wordline driver array is also formed on the upper surface of the third chip 300, the sub-wordline driver array also requires a through-silicon via TSV (or Nano-TSV) to connect to the first memory array Bottom Array, and thus the load of the first wordline WL1 is greater than the load of the second wordline WL2. Therefore, the driving capability required by the first wordline WL1 is greater than the driving capability required by the second wordline WL2. Therefore, the driving capability of the first sub-wordline driver SWD1 may be designed to be greater than the driving capability of the second sub-wordline driver SWD2, thereby balancing the read/write timings of the first memory array and the second memory array.

FIG. 6 is a schematic diagram showing another detailed layout of a memory provided according to an embodiment of the present disclosure. In FIG. 6, like the sense amplifier SA, the sub-wordline driver array is also formed on the lower surface of the third chip 300. The sub-wordline driver array also requires a through-silicon via TSV (or Nano-TSV) to connect to the second memory array Top Array, and thus the load of the first wordline WL1 is less than the load of the second wordline WL2. Therefore, the driving capability required by the first wordline WL1 is less than the driving capability required by the second wordline WL2. Therefore, the driving capability of the first sub-wordline driver SWD1 may be designed to be less than the driving capability of the second sub-wordline driver SWD2, thereby balancing the read/write timings of the first memory array and the second memory array.

The sub-wordline driver SWD may be of a structure of a conventional sub-wordline driver SWD. For the first sub-wordline driver SWD1 and the second sub-wordline driver SWD2, simply by designing them with different sizes or different power supply voltages, their driving capabilities can be adjusted to be different. The sub-wordline driver SWD with a stronger driving capability has a larger size or receives a larger power supply voltage VDD.

With continued reference to FIGS. 3 and 6, the core region circuit further includes a row decoder XDEC, a column decoder YDEC, and a low dropout linear regulator LDO. The row decoder XDEC is configured to decode a row address and provide the row address for the activation of the first memory array and the second memory array. The column decoder YDEC is configured to decode a column address and provide the column address for the activation of the first memory array and the second memory array. The low dropout linear regulator LDO steps down and denoises a received external voltage to provide an internal power supply for the internal core region circuit. The low dropout linear regulator LDO is connected to the capacitors Cap on the second chip 200 and the fourth chip 400 and uses the capacitors Cap as terminals to provide a power supply voltage for the second chip 200 and the fourth chip 400.

The core region circuit on the third chip 300 serves as an intermediate circuit between the logic circuit on the first chip 100 and the first memory array and the second memory array. The core region circuit is different from the logic circuit. The core region circuit delivers the power supply and signals sent by the logic circuit to the memory arrays, and delivers data information read from the memory arrays to the logic circuit.

With continued reference to FIG. 3, the core region circuit is disposed on a side, facing the fourth chip 400, of the third chip 300, and the electrical connection path between the core region circuit and the first chip 100 includes: a through-silicon via Nano-TSV penetrating through the third chip 300, hybrid bonding Hybrid Bond between the third chip 300 and the second chip 200, a through-silicon via Nano-TSV penetrating through the second chip 200, and hybrid bonding Hybrid Bond between the second chip 200 and the first chip 100.

In some embodiments, the electrical connection path further includes metal wiring layers on the surfaces of the chips. For example, the core region circuit is connected to the through-silicon via Nano-TSV penetrating through the third chip 300 through the metal wire layer on the surface of the third chip 300, the through-silicon via Nano-TSV penetrating through the third chip 300 is connected to the metal wiring layer on the surface of the second chip through back hybrid bonding Hybrid Bond, the metal wiring layer on the surface of the second chip is connected to the through-silicon via Nano-TSV penetrating through the second chip 200, and the through-silicon via Nano-TSV penetrating through the second chip 200 is connected to the front side of the first chip through hybrid bonding Hybrid Bond.

Thus, an electrical path from the core region circuit of the third chip 300 to the lead-out pads PAD1 and PAD2 of the first chip 100 is formed, and data information stored in the first memory array and the second memory array is read or data information is written into the first memory array and the second memory array.

With continued reference to FIG. 6, in some other embodiments, the core region circuit is disposed on a side, facing the second chip 200, of the third chip 300, and the electrical connection path between the core region circuit and the first chip 100 includes: hybrid bonding Hybrid Bond between the third chip 300 and the second chip 200, a through-silicon via Nano-TSV penetrating through the second chip 200, and hybrid bonding Hybrid Bond between the second chip 200 and the first chip 100.

In some embodiments, the electrical connection path further includes metal wiring layers on the surfaces of the chips. For example, the core region circuit is connected to the metal wiring layer on the surface of the second chip through hybrid bonding Hybrid Bond between the front side of the third chip 300 and the second chip 200, the metal wiring layer on the surface of the second chip is connected to the through-silicon via Nano-TSV penetrating through the second chip 200, and the through-silicon via Nano-TSV penetrating through the second chip 200 is connected to the front side of the first chip through hybrid bonding Hybrid Bond.

Thus, an electrical path from the core region circuit of the third chip 300 to the lead-out pads PAD1 and PAD2 of the first chip 100 is formed, and data information stored in the first memory array and the second memory array is read or data information is written into the first memory array and the second memory array. In addition, because the front side of the third chip 300 faces the second chip 200 in the embodiment of FIG. 6, compared with the embodiment of FIG. 3, the signal transmission path between the core region circuit and the logic circuit has fewer through-silicon vias (Nano-TSV). This reduces the electrical connection load from the core region circuit to the logic circuit, and therefore a better read/write delay of the chip may be achieved.

Referring to FIGS. 3 and 6, there are two types of electrical connection paths, i.e., a signal transmission path Signal Paths and a power transmission path Power Paths. The signal transmission path Signal Paths includes undecoded row and column address information, a test mode, a read/write control signal, and the like. The power transmission path includes a power control signal. Only a single path of each type is shown in the figure for illustration. However, it can be understood that the quantity of these signal transmission paths may be specifically set based on the actual requirement.

Those of ordinary skill in the art can understand that the foregoing implementations are specific embodiments of practicing the present application, while in practical applications, various changes can be made to the implementations in form and detail without departing from the spirit and scope of the present application. Any person skilled in the art can make respective changes and modifications without departing from the spirit and scope of the present application, and the protection scope of the present application is defined by the appended claims.

What is claimed is:

1. A memory, comprising a first chip, a second chip, a third chip, and a fourth chip stacked in sequence along a first direction, wherein a logic circuit is formed on the first chip, a first memory array is formed on the second chip, a core region circuit is formed on the third chip, and a second memory array is formed on the fourth chip.

2. The memory according to claim 1, wherein the core region circuit comprises a sense amplifier.

3. The memory according to claim 2, wherein the sense amplifier is connected to the first memory array through a first bitline, and the sense amplifier is connected to the second memory array through a first complementary bitline.

4. The memory according to claim 3, wherein the sense amplifier has different driving capabilities for the first bitline and the first complementary bitline.

5. The memory according to claim 4, wherein the sense amplifier comprises a first inverter and a second inverter connected end to end, and the first inverter and the second inverter have different driving capabilities.

6. The memory according to claim 1, wherein the core region circuit comprises a sub-wordline driver array, the sub-wordline driver array comprises a first sub-wordline driver and a second sub-wordline driver, the first sub-wordline driver is connected to the first memory array through a first sub-wordline, and the second sub-wordline driver is connected to the second memory array through a second sub-wordline.

7. The memory according to claim 6, wherein the first sub-wordline driver and the second sub-wordline driver have different driving capabilities.

8. The memory according to claim 1, wherein the core region circuit further comprises a row decoder, a column decoder, and a low dropout linear regulator.

9. The memory according to claim 1, wherein the core region circuit is disposed on a side, facing the fourth chip, of the third chip, and an electrical connection path between the core region circuit and the first chip comprises: a through-silicon via penetrating through the third chip, hybrid bonding between the third chip and the second chip, a through-silicon via penetrating through the second chip, and hybrid bonding between the second chip and the first chip.

10. The memory according to claim 1, wherein the core region circuit is disposed on a side, facing the second chip, of the third chip, and an electrical connection path between the core region circuit and the first chip comprises: hybrid bonding between the third chip and the second chip, a through-silicon via penetrating through the second chip, and hybrid bonding between the second chip and the first chip.
